(19) United States
(12) Patent Application Publication
(10) Pub. No.: US 2011/0079713 A1
(43) Pub. Date: Apr. 7, 2011

(54) UNI-AXIS TYPE LENS MODULE FOR THERMAL IMAGING CAMERA

(75) Inventors: Hyun-Kyu Kim, Daejeon (KR); Chang-Min Ok, Daejeon (KR)

(73) Assignee: TOPINS CO., LTD., Daejeon (KR)

(21) Appl. No.: 12/783,254

(22) Filed: May 19, 2010

(30) Foreign Application Priority Data
Oct. 7, 2009 (KR) 10-2009-0094899

(51) Int. Cl. H01L 31/0232; G01J 5/08

(52) U.S. Cl. 250/330

(57) ABSTRACT

Disclosed herein is a Uni-axis type lens module for a thermal imaging camera. The Uni-axis type lens module includes an object lens facing an object, receiving light from the object to capture an image of the object and transmitting visible rays and far infrared rays through one optical axis to integrate the visible rays and the far infrared rays; a beam splitter located behind the object lens in the direction of the optical axis, reflecting far infrared rays from lights that pass through the object lens and transmitting visible rays from the lights; a far-infrared imaging lens located in the direction of the optical axis of the far infrared rays reflected from the beam splitter, receiving the far infrared rays that reflect from a fold mirror and forming an image on a far-infrared sensor that converts an optical image into a thermal image signal; and a visible light imaging sensor located in the direction of the optical axis of the visible rays that pass through the beam splitter, arranged behind the beam splitter, receiving the visible rays that pass through the beam splitter and forming an image on a CCD sensor that converts an optical image into an actual image signal. Accordingly, images of visible rays and far infrared rays can be simultaneously captured to acquire distinct images.

### BACKGROUND OF THE INVENTION

1. Field of the Invention

The present invention relates to a Uni-axis type lens module for a thermal imaging camera and, more particularly, to a Uni-axis type lens module for a thermal imaging camera capable of simultaneously capturing images of visible rays and far infrared rays.

2. Background of the Related Art

A thermal imaging camera is applied to thermal vision for medical purposes and used as a night monitoring sensor of vehicles for commercial purposes. Furthermore, the thermal imaging camera is increasingly used for forest fire surveillance, fire protection, industrial purposes and research and development.

Moreover, the thermal imaging camera can complement a CCD (Charge-Coupled Device) camera used as a monitoring camera, which cannot capture images at night, and thus demands for the thermal imaging camera rapidly are increasing.

The thermal imaging camera captures images using a far-infrared lens even when there is no light at night. Specifically, a far-infrared sensor photoelectric-converts an optical image input from the far-infrared lens to generate a digital thermal image signal readable by a computer (PC or notebook computer) so as to acquire a thermal image.

Although the thermal imaging camera can obtain images using the far-infrared lens at night, as described above, black and white images are acquired because the thermal imaging camera senses a radiant energy difference generated from an object to obtain an image.

Accordingly, the thermal imaging camera cannot obtain distinct images as compared to the CCD camera. If a thermal image and a CCD image are simultaneously obtained, the thermal image will be used for various purposes.

For reference, the CCD camera captures an image of an object using a visible light lens and photoelectric-converts an optical image input from the visible light lens through a CCD sensor to generate a digital CCD image signal (Hereinafter, ‘actual image signal’) readable by a computer so as to acquire an image.

### SUMMARY OF THE INVENTION

Accordingly, the present invention has been made in view of the above-mentioned problems occurring in the prior art, and it is a primary object of the present invention to provide a Uni-axis type lens module for a thermal imaging camera capable of simultaneously capturing images of visible rays and far infrared rays to acquire distinct images.

To accomplish the above object of the present invention, according to the present invention, there is provided a Uni-axis type lens module for a thermal imaging camera, which includes an object lens facing an object, receiving light from the object to capture an image of the object and transmitting visible rays and far infrared rays through one optical axis to integrate the visible rays and the far infrared rays; a beam splitter located behind the object lens in the direction of the optical axis, reflecting far infrared rays from lights that pass through the object lens and transmitting visible rays from the lights; a far-infrared imaging lens located in the direction of the optical axis of the far infrared rays reflected from the beam splitter, receiving the far infrared rays that reflect from a fold mirror and forming an image on a far-infrared sensor that converts an optical image into a thermal image signal; and a visible light imaging sensor located in the direction of the optical axis of the visible rays that pass through the beam splitter, arranged behind the beam splitter, receiving the visible rays that pass through the beam splitter and forming an image on a CCD sensor that converts an optical image into an actual image signal.

The object lens may be made of ZnSe or ZnS that can transmit both visible rays and far infrared rays.

The beam splitter may be made of optical glass (BK7) with a front face on which far-infrared reflecting coating is performed, which can transmit visible rays.

The F number of the far-infrared imaging lens may be smaller than or equal to 1.6.

The F number of the visible light imaging lens may be smaller than or equal to 4.

The far-infrared sensor may be a uncooled type far-infrared sensor.

The thermal imaging camera can simultaneously capture distinct images of visible rays and far infrared rays.

A visible light lens and a far-infrared lens have different transmission characteristics according to wavelengths, and thus two independent optical systems, that is, a visible light optical system and a far-infrared optical system, are required. Accordingly, the volume of a camera having the two optical systems increases and it is difficult to capture images of the same object at the same viewing angle. However, the thermal imaging camera according to the present invention can simultaneously take pictures of the same object on the same optical axis at the same viewing angle, and thus images of visible rays and far infrared rays can be simultaneously captured to acquire distinct visible-ray image (actual image) and thermal image of the same target. Accordingly, the images of the target can be usefully used when the images are analyzed.

### BRIEF DESCRIPTION OF THE DRAWINGS

The above and other objects, features and advantages of the present invention will be apparent from the following detailed description of the preferred embodiments of the invention in conjunction with the accompanying drawings, in which:

FIG. 1 illustrates connection of a computer and a thermal imaging camera equipped with a Uni-axis type lens module for a thermal imaging camera according to the present invention;

FIG. 2 illustrates the Uni-axis type lens module for a thermal imaging camera according to the present invention;

FIG. 3 illustrates a far-infrared optical system in the Uni-axis type lens module according to the present invention; and

FIG. 4 illustrates a visible light optical system in the Uni-axis type lens module according to the present invention.

### DETAILED DESCRIPTION OF THE PREFERRED EMBODIMENT

Hereinafter, the present invention will be described in detail by explaining preferred embodiments of the invention with reference to the attached drawings.

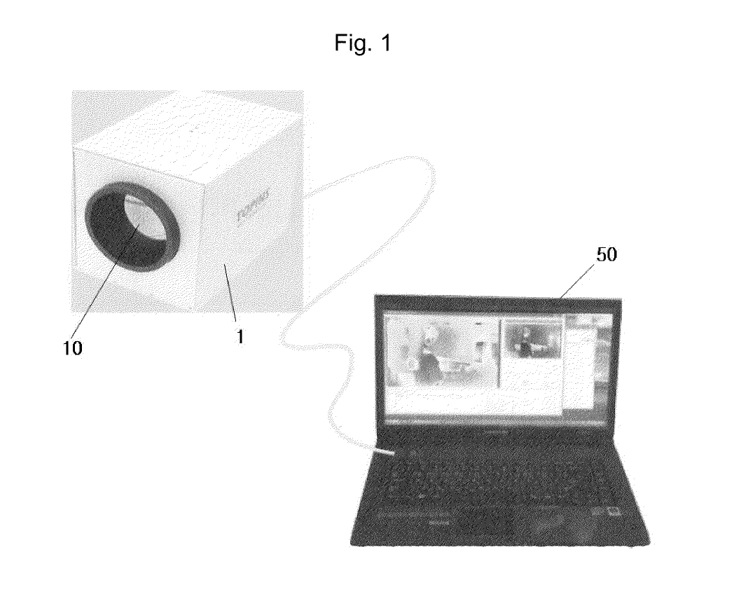

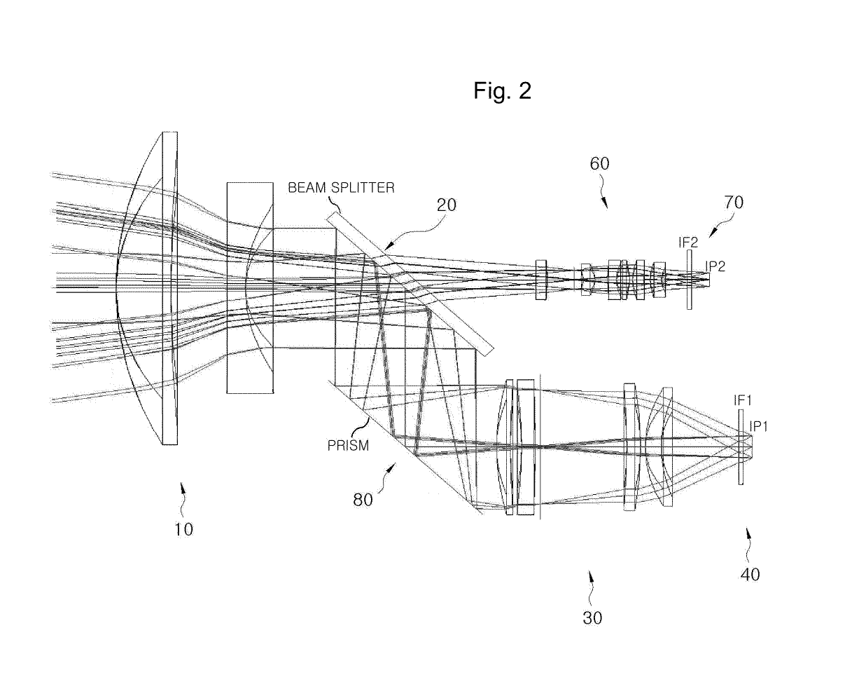

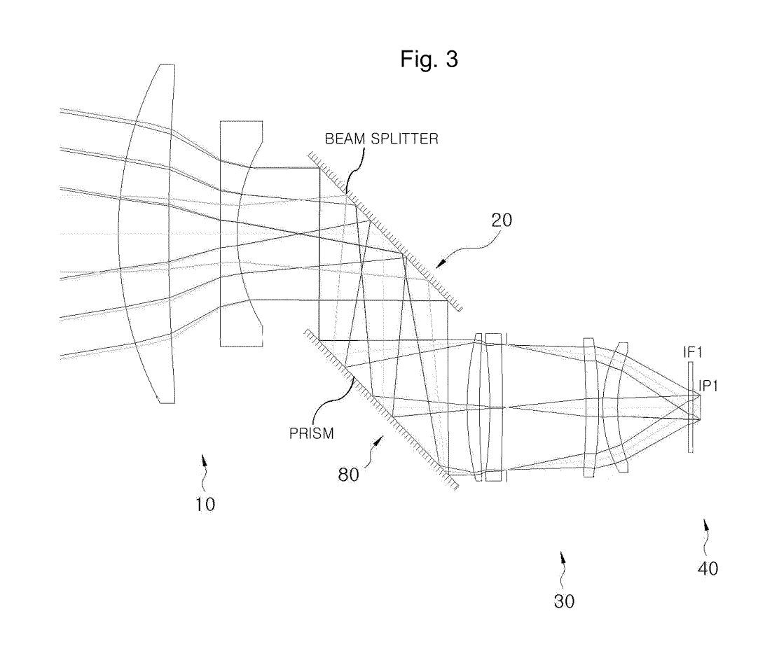

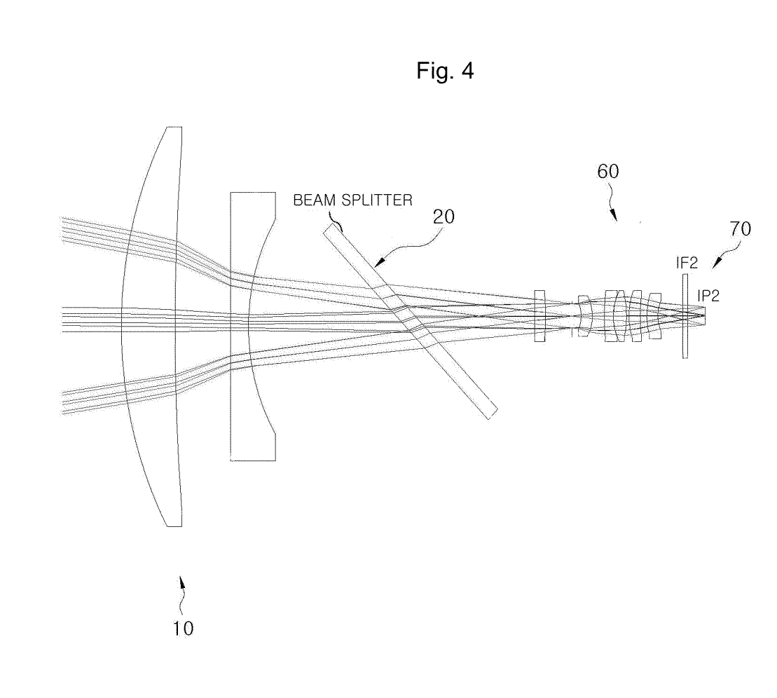

FIG. 1 illustrates connection of a computer and a thermal imaging camera equipped with a Uni-axis type lens module for a thermal imaging camera according to the present invention and FIG. 2 illustrates the Uni-axis type lens module for a thermal imaging camera according to the present invention. FIG. 3 illustrates a far-infrared optical system in the Uni-axis type lens module according to the present invention and FIG. 4 illustrates a visible light optical system in the Uni-axis type lens module according to the present invention.

Referring to FIGS. 1, 2, 3 and 4, the Uni-axis type lens module for a thermal imaging camera according to the present invention is set in a case 1 that forms the external appearance of the thermal imaging camera and protects the thermal imaging camera from the outside and includes an object lens 10.

The object lens 10 is set in the case 1 such that the object lens 10 is exposed from the front side of the case 1 and receives light from an object to capture an image. The object lens 10 transmits visible rays and far-infrared rays through one optical axis to integrate the visible rays and the far-infrared rays.

The object lens 10 is made of ZnSe that can simultaneously transmit visible rays and far-infrared rays to integrate optical axes of the visible rays and far-infrared rays, and thus it is possible to simultaneously take pictures of the same object on the same optical axis at the same viewing angle.

The object lens 10 may have a transmission wavelength in the range of 0.4 to 14.0 μm. Here, wavelengths of 7.5 through 14.0 μm correspond to far infrared rays and wavelengths of 0.4 through 0.7 μm correspond to visible rays.

The object lens 10 may be made of ZnS instead of ZnSe to transmit visible rays and far infrared rays through the one optical axis to integrate the visible rays and far infrared rays.

A beam splitter 20 is located behind the object lens 10 in the direction of the optical axis.

The beam splitter 20 transmits visible rays from lights that pass through the object lens 10 and reflects far infrared rays from the lights.

The beam splitter 20 is made of optical glass (BK7) to transmit the visible rays and reflects the far infrared rays.

A far-infrared imaging lens 30 is located in the direction of the optical axis of the far infrared rays reflected from the beam splitter 20.

The far-infrared imaging lens 30 receives the far infrared rays reflected from the beam splitter 20 and forms an image on a far-infrared sensor 40.

The far-infrared sensor 40 photoelectric-converts an optical image captured by the object lens 10 and input from the far-infrared imaging lens 30 to generate a thermal image signal readable by a computer (PC or notebook computer) so as to acquire a thermal image.

The far-infrared sensor 40 is classified into cryogenic cooled type and uncooled type. The cryogenic cooled far-infrared sensor requires an additional cooling device used to cool the sensor to a low temperature of 77K. However, the uncooled type far-infrared sensor does not need an additional cooling device since it can be used at room temperature, and thus the size and weight of the uncooled type far-infrared sensor are easily reduced. Accordingly, the present invention employs the uncooled type far-infrared sensor.

The uncooled type far-infrared sensor 40 has F number smaller than 1.6, for example, between 1.0 to 1.6, and thus the uncooled type far-infrared sensor 40 is restrictedly used and can be used only for far infrared rays. However, the present invention can employ the uncooled type far-infrared sensor 40 because the present invention satisfies the characteristic of the uncooled type far-infrared sensor.

An exemplary far-infrared optical system may have field of view (FOV) of 24° on the X-axis and 18° on the Y-axis, effective focal length (EFL) of 17.69 mm and F number smaller than or equal to 1.2. Here, a pixel format is configured of 320×240 pixels and a pixel size is 25×25 μm.

A visible light imaging lens 60 is located behind the beam splitter 20.

The visible light imaging lens 60 is disposed in the direction of the optical axis of the visible rays that pass through the beam splitter 20.

The visible light imaging lens 60 receives the visible rays that pass through the beam splitter 20 and forms an image on a CCD sensor 70.

The CCD sensor 70 photoelectric-converts an optical image captured by the object lens 10 and input from the visible light imaging lens 60 to generate an actual image signal readable by a computer 50 so as to acquire an image.

An exemplary visible light optical system may have FOV of 24° on the X-axis and 18° on the Y-axis, EFL of 11.14 mm and F number smaller than or equal to 4.0, preferably, F number in the range of 1.0 to 4.0. Here, a pixel format is configured of 640×480 pixels and a pixel size is 7.4×7.4 μm.

A reflector 80 such as a mirror, which can reflect the far infrared rays reflected from the beam splitter 20 in an arbitrary direction, may be arranged in the direction of the optical axis of the far infrared rays to change the positions of the far-infrared imaging lens 30 and the far-infrared sensor 40 so as to reduce the volume of the Uni-axis type lens module.

As described above, the optical axes of visible rays and far infrared rays are integrated using the object lens 10 made of a material that simultaneously transmits the visible rays and far infrared rays, the beam splitter 20 is located behind the object lens 10 to transmit visible rays and reflect far infrared rays, and the far-infrared sensor 40 and the CCD sensor 70 are respectively disposed on focuses of the visible rays and far infrared rays. Accordingly, it is possible to simultaneously capture images of the same object on the same optical axis at the same viewing angle to simultaneously acquire an actual image and a thermal image of the same object.

According to the present invention, the thermal imaging camera can simultaneously capture images of visible rays and far infrared rays to obtain distinct thermal images.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A Uni-axis type lens module for a thermal imaging camera, comprising:
an object lens 10 facing an object, receiving light from the object to capture an image of the object and transmitting visible rays and far infrared rays through one optical axis to integrate the visible rays and the far infrared rays;
a beam splitter 20 located behind the object lens 10 in the direction of the optical axis, reflecting far infrared rays from lights that pass through the object lens 10 and transmitting visible rays from the lights;
a far-infrared imaging lens 30 located in the direction of the optical axis of the far infrared rays reflected from the beam splitter 20, receiving the far infrared rays that reflect from a fold mirror and forming an image on a far-infrared sensor 40 that converts an optical image into a thermal image signal; and
a visible light imaging sensor 60 located in the direction of the optical axis of the visible rays that pass through the beam splitter 20, arranged behind the beam splitter 20, receiving the visible rays that pass through the beam splitter 20 and forming an image on a CCD sensor 70 that converts an optical image into an actual image signal,
wherein the thermal imaging camera simultaneously capture images of visible rays and far infrared rays at the same viewing angle.

2. The Uni-axis type lens module of claim 1, wherein the object lens 10 is made of ZnSe or ZnS.

3. The Uni-axis type lens module of claim 1, wherein the beam splitter 20 is made of optical glass (BK7).

4. The Uni-axis type lens module of claim 1, wherein the F number of the far-infrared imaging lens 30 is smaller than or equal to 1.6.

5. The Uni-axis type lens module of claim 1, wherein the F number of the visible light imaging lens 60 is smaller than or equal to 4.

6. The Uni-axis type lens module of claim 1, wherein the far-infrared sensor 40 is a uncooled type far-infrared sensor.
